(19) United States
(12) Patent Application Publication
(10) Pub. No.: US 2013/0285197 A1
(43) Pub. Date: Oct. 31, 2013

(54) Semiconductor Devices and Methods of Manufacturing and Using Thereof

(71) Applicants: Ralf Otremba, Kaufbeuren (DE); Marco Seibt, Villach (AT); Uwe Kirchner, Feldkirchen (AT)

(72) Inventors: Ralf Otremba, Kaufbeuren (DE); Marco Seibt, Villach (AT); Uwe Kirchner, Feldkirchen (AT)

(73) Assignee: Infineon Technologies AG, Neubiberg (DE)

(21) Appl. No.: 13/458,848

(22) Filed: Apr. 27, 2012

(51) Int. Cl. H01L 27/00; H01L 21/50

(52) U.S. Cl. 257/531; 257/528; 257/532; 438/107; 257/E27.001; 257/E21.499

(57) ABSTRACT

A semiconductor device includes at least one first semiconductor element and two interconnectors for electrically coupling the at least one first semiconductor element to external. A spacing between the two interconnectors corresponds to a size of a second semiconductor element. The second semiconductor element can be affixed between the two interconnectors.

### TECHNICAL FIELD

The invention relates to semiconductor devices, methods of manufacturing the semiconductor devices, a method of manufacturing an electronic device incorporating at least one of the semiconductor devices, and a method of using a set of semiconductor devices.

### BACKGROUND

Semiconductor devices may comprise one or both of active semiconductor elements and passive semiconductor elements. Active semiconductor elements may comprise, for example, transistors, diodes, chips, etc. Passive semiconductor elements may comprise, for example, resistors, capacitors, inductors, etc. Electronic devices can comprise one or more semiconductor devices and/or one or more semiconductor elements.

There is a general trend of progressively shrinking semiconductor devices. For example in the field of power semiconductor devices, operating at higher frequency allows smaller devices and elements, posing corresponding requirements on integration into electronic devices, minimization of switching losses, etc.

### SUMMARY OF THE INVENTION

According to one embodiment, a semiconductor device comprises at least one first semiconductor element. Two interconnectors are provided for electrically coupling the at least one first semiconductor element to external. A spacing between the two interconnectors corresponds to a size of a second semiconductor element.

### BRIEF DESCRIPTION OF THE DRAWINGS

The accompanying drawings are included to provide a thorough understanding of various embodiments and are incorporated in and constitute a part of this specification. The drawings illustrate different embodiments and together with the description serve to explain miscellaneous aspects thereof. Other embodiments, aspects and advantages will be readily appreciated and become better understood by reference to the following detailed description.

In the figures and the description like reference numerals are generally utilized to refer to like elements throughout. It is to be noted that the various elements and structures shown in the figures are not necessarily drawn to scale. Features and/or elements are illustrated with particular dimensions relative to each other primarily for sake of clarity and ease of understanding; as a consequence, relative dimensions in factual implementations may differ substantially from those illustrated herein.

FIG. 1 schematically illustrates a first embodiment of a semiconductor device;

FIG. 2 schematically illustrates a second embodiment of a semiconductor device;

FIG. 3 is circuit diagram comprising power packages and passive power semiconductor elements;

FIGS. 4A to 4C illustrate in perspective, top and side views a first embodiment of a power package and a passive semiconductor element mounted onto its leads;

FIGS. 5A to 5D illustrate in perspective, bottom and side views a second embodiment of a power package and a passive semiconductor element mounted onto contact pads thereof;

FIGS. 6A and 6B illustrate in bottom and side views a third embodiment of a power package and a passive semiconductor element mounted stack-wise thereto;

FIG. 6C illustrates in side view a fourth embodiment of a power package and a passive semiconductor element mounted stack-wise thereto;

FIG. 7 illustrates in top view a fifth embodiment of a power package and a passive semiconductor element integrated therewithin onto its interconnectors;

FIG. 8 illustrates in partial top view a sixth embodiment of a power package and a passive semiconductor element integrated therewithin onto its interconnectors;

FIG. 9 is a flow diagram illustrating a first embodiment of a method of manufacturing a semiconductor device;

FIG. 10 is a flow diagram illustrating a second embodiment of a method of manufacturing a semiconductor device;

FIG. 11 is a flow diagram illustrating an embodiment of a method of manufacturing an electronic device;

FIG. 12 is a flow diagram illustrating an embodiment of a method of using a set of semiconductor devices; and

FIG. 13 schematically illustrates a set of semiconductor devices and a set of semiconductor elements.

### DETAILED DESCRIPTION OF ILLUSTRATIVE EMBODIMENTS

In the following description, for purposes of explanation and not limitation, by reference to the accompanying drawings, various embodiments are set forth including many specific details thereof in order to provide a thorough understanding of the current invention. It is to be understood that other embodiments, which differ in one or more of these specific details, can be practiced without departing from the scope of the present invention. Accordingly, the following description is intended for illustrative, non-limiting purposes only, and the scope of the present invention shall be defined by the appended claims.

It will further be appreciated that the features of the various exemplary embodiments described herein can be combined with each other, unless specifically noted otherwise.

Semiconductor devices are described below. Various embodiments of semiconductor devices comprise one or more semiconductor elements. Semiconductor devices may be implemented as packages, for example WLPs (Wafer Level Packages), CSPs (Chip Scale Packages), power packages, wherein the packages may result for example from various wafer level packaging techniques. Semiconductor devices may, for example, be adapted for HV (High Voltage) applications, and/or other applications. Generally, semiconductor devices and/or semiconductor elements can be manufactured based on semiconducting materials such as Si, SiC, SiGe, GaAs, etc. and may additionally or alternatively comprise inorganic and/or organic materials that are not semiconductors, such as fully conductive materials, insulators, metals, plastics, etc.

Semiconductor elements as referred to herein can be implemented as active or passive semiconductor elements. Active semiconductor elements are generally understood as being adapted for an amplification function and/or for a controlling function, which is in contrast to passive semiconductor elements understood as not comprising amplifier and/or controlling functionality. Non-limiting examples of passive elements are resistors, capacitors, inductors, etc. Non-limiting examples of active elements are diodes, flip-chip diodes, transistors, IGBTs, ICs (Integrated Circuits), semiconductor chips, etc. An active element may also implement a combination of one or more of the aforementioned elements; for example, an active element may comprise a combination of a transistor and a diode.

A power semiconductor device, for example a power package, may comprise at least one power semiconductor element.

Semiconductor elements as referred to herein may be implemented as power semiconductor elements. For example, active power semiconductor elements may comprise one or more of power transistors, power diodes, etc. Power semiconductor chips or circuits can, for example, comprise power bipolar transistors, IGBTs (insulated gate bipolar transistors), power MOSFETs (metal oxide semiconductor field-effect transistors), etc. Power circuits or power chips may additionally include control circuitry, control logic, logic ICs, microprocessors, micro-controllers, etc.

According to one approach practiced in the field, a semiconductor element is categorized as a power element if it is adapted for a maximum current of, for example, 1 ampere or more. Additionally or alternatively, an element can be categorized as a power element if it is adapted for a maximum voltage of, for example, 24 volts or more, or 50 volts or more. Additionally or alternatively, an element can be categorized as a power element if it is adapted for a maximum power loss of, for example, 1 watt or more, or 2 watts or more. Additionally or alternatively, a structural definition of a power element may comprise the requirement that (voltage) supply means such as power electrodes are arranged on both an upper and a lower surface area of the element.

Electronic devices are referred to herein, which may comprise one or more semiconductor devices and/or one or more (further) semiconductor elements. According to various embodiments, an electronic device may comprise at least one semiconductor device and at least one passive semiconductor element. The semiconductor device may comprise an active semiconductor element. The passive semiconductor element may be arranged external to a housing of the semiconductor device, or may be integrated within a housing of the semiconductor device.

Various embodiments of electronic devices may comprise one or more carriers, such as a PCB (Printed Circuit Board) complemented by one or more adapter cards or boards, e.g., a PFC (Power Factor Correction) adapter board, and/or may comprise one or more housings, via connections, etc. Referring to semiconductor devices, embodiments thereof may be provided according to SMT (Surface Mounted Technology), through-hole technology, chip carrier technology, Pin Grid Array technology, Flat Package or Small Outline Packaging technology, CSP technology, Ball Grid Array technology, etc. For example, exemplary embodiments of semiconductor devices may comprise packages with leads or leadless packages.

Embodiments of semiconductor devices and/or electronic devices can be adapted for power applications, HV applications, etc. An electronic device can implement, for example, a power supply unit, such as a switched mode power supply, power inverter, AC/DC converter, DC/DC converter, power controller, etc. A power supply may for example implement a ballast, for example an electronic ballast, lamp ballast, etc.

Various embodiments of semiconductor devices referred to herein comprise one or more interconnectors, which may implement, for example, a second level interconnect, i.e. an interconnection between the semiconductor device and an external component such as, e.g., a PCB and/or other board of an electronic device, other semiconductor devices included within the electronic device, etc.

The interconnectors may comprise contact terminals for providing electrical connectivity to external. Various embodiments of contact terminals comprise leads, pins, contact pads, etc. For providing connectivity within a semiconductor device, interconnectors may comprise electrical conduction lines, electrical conduction paths, and/or other electrical connecting lines, routes or tracks traversing the semiconductor device. Regarding a first level interconnect, i.e. an interconnection with a semiconductor element integrated within the semiconductor device, further electrical coupling may be provided, for example, by wire bonding provided between the semiconductor element and the one or more interconnectors. According to one example, the interconnectors may be part of a leadframe.

A spacing between a pair of interconnectors is referred to herein. The spacing is understood as indicating a distance (separation) between a point at the first of the pair of interconnectors and a point at the second of the pair of interconnectors. According to various embodiments the spacing may indicate a pitch, wherein the pitch measures a center-to-center distance of two contact terminals, e.g., contact pins, leads or pads of a pair of interconnectors. Therefore a pitch can refer to a pin separation, lead separation, or separation of any kind of contact terminals provided by the semiconductor device.

Additionally or alternatively, a spacing may measure a separation of two interconnectors internally within a semiconductor device. According to one example, two interconnector conductor paths traversing a housing of a semiconductor path can have a spacing. According to a further example, a spacing may measure a gap between an area on a first interconnector and an area on a second interconnector, wherein the areas are provided for connecting to a semiconductor element integrated in the semiconductor device.

According to various embodiments, a semiconductor element is operatively mounted on a pair of interconnectors, which, as understood herein, may include that the semiconductor element is electrically connected with each interconnector of the pair of interconnectors. A mounting process may comprise, for example, soldering, e.g., reflow soldering, diffusion soldering, adhesive bonding, wire bonding, etc. Whether or not a semiconductor element is mounted thereto, the interconnectors may be available for further connections, for example, to external.

According to various embodiments, a semiconductor device may have a first semiconductor element integrated therewithin, and a second semiconductor element may be mounted to a pair of interconnectors of the device. It is to be understood that one embodiment of a manufacturing process may include that the first semiconductor element is integrated into the device, and that the second semiconductor element is mounted to the pair of interconnectors in the same process. According to another embodiment, in a first manufacturing process the first semiconductor element is integrated into the device, and in a second manufacturing process the second semiconductor element is mounted to the pair of interconnectors. The first and the second process can be separate processes. For example, the first process can be performed in a first manufacturing area, and the second process can be performed in a second manufacturing area, wherein the first and the second manufacturing areas are separate areas.

The first process may comprise manufacturing a set of semiconductor devices with different interconnector spacings, e.g., pitch sizes. The second process can comprise selecting one of a set of semiconductor elements with a dimension thereof conforming to one of the interconnector spacings provided by the set of semiconductor devices. The dimension may for example relate to a length of the semiconductor element.

According to various embodiments, a process of mounting a semiconductor device onto a carrier, such as a board, and a process of mounting a semiconductor element to interconnectors of the semiconductor device is performed in parallel, for example as one process. For instance, a single soldering process may be performed. As a specific, non-limiting example, a process of mounting a semiconductor device to a carrier and mounting a semiconductor element to a pair of interconnectors of the semiconductor device can be performed in one and the same reflow oven.

During the manufacturing of a semiconductor device, a soldering and/or adhesive material can be deposited on interconnector contact terminals. A mounting of a semiconductor element on the interconnectors, which can be performed in a separate process, may make use of the previously deposited soldering and/or adhesive material. According to various embodiments, the previously deposited soldering and/or adhesive material is used at the same time for establishing an electrical, mechanical, and/or thermal coupling of the semiconductor device, e.g., via one or more of the interconnectors, to a PCB or other external.

Various embodiments of semiconductor devices may comprise an encapsulation such as, for example, a housing or casing. According to one example, a semiconductor element such as a chip, power chip, etc. can be encapsulated via molding. The semiconductor device may comprise a carrier. The carrier may be encapsulated in part or totally. One or more inter-connectors may traverse the encapsulation for providing connectivity to external.

FIG. 1 schematically illustrates an embodiment 100 of a semiconductor device. The device 100 comprises at least one first semiconductor element 102 and two interconnectors 104 for electrically coupling the at least one first semiconductor element 102 to external. A spacing 106 between the two interconnectors 104 corresponds to a size of a second semiconductor element 108. The element 108 may or may not be part of the device 100. For example, the device 100 may be provided for optional or later addition of the element 108.

Providing the element 108 may comprise affixing the element 108 to one or both of the interconnectors 104, e.g., via soldering. According to various embodiments, the element 108 and device 100 may be provided on a common carrier, such as a PCB, with short conducting lines or paths or wire bonding, etc., connecting the element 108 with external contact terminals 110 of the interconnectors 104. The term ‘short’ may mean that a separation between the element 108 and the contact terminals 110 is less than a size of the element 108, such as its width 112 or length 114, or is less than 5 millimeters, or less than 2 millimeters, or less than 1 millimeter, or less than 0.5 millimeters.

According to some embodiments, in case of a short separation between the element 108 and the device 100, the aspect of the spacing 106 between the interconnectors 104 corresponding to a size of the second element 108 may include configurations wherein the spacing 106 differs from a size 114 of element 108. In these configurations, a synchronization of spacing 106 to size 114 may be provided by diverging or converging conductor paths, wires, etc. traversing the short distance between element 108 and device 100.

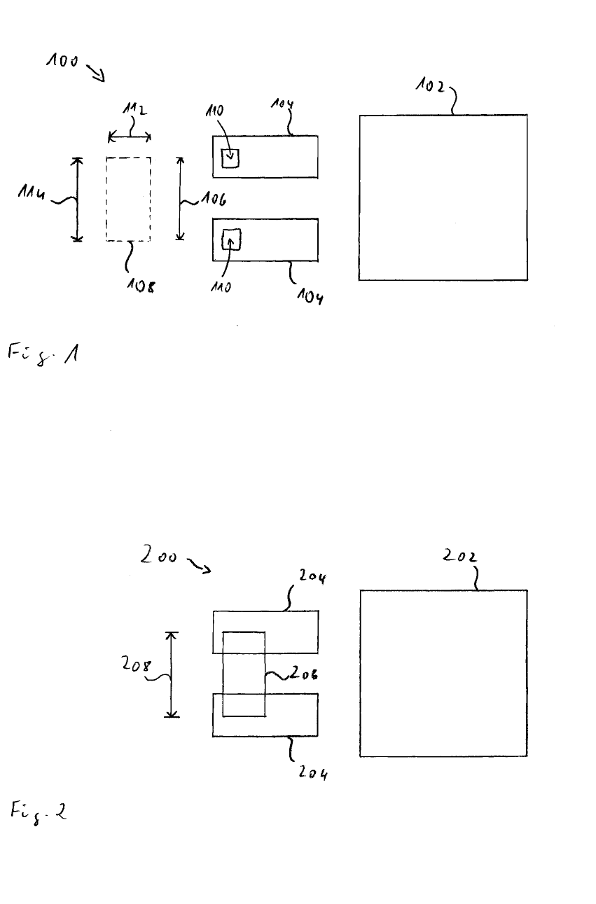

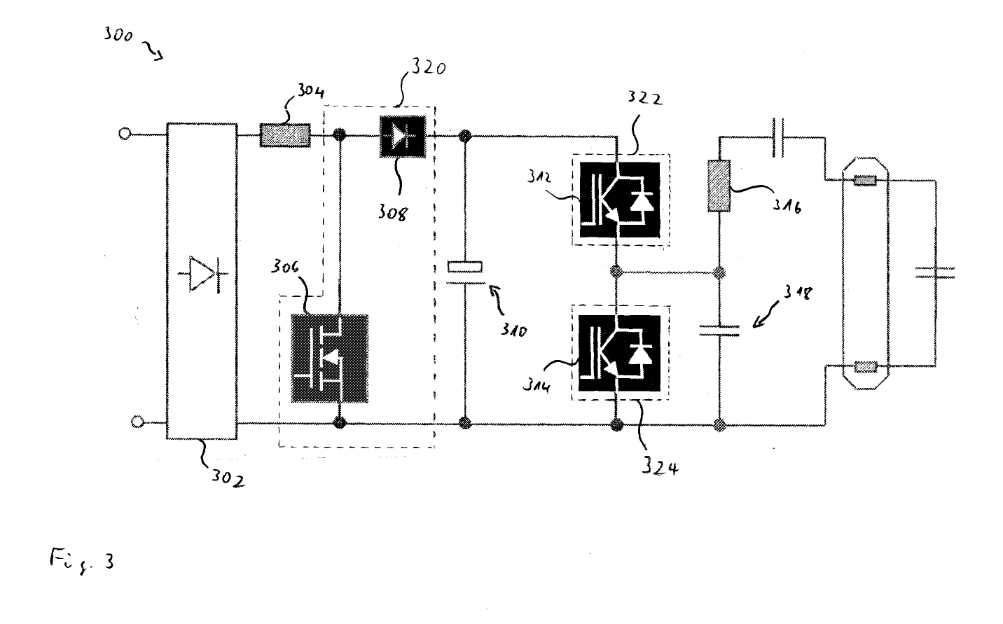

FIG. 2 schematically illustrates an embodiment 200 of a semiconductor device. The device 200 comprises at least one first semiconductor element 202, two interconnectors 204 for electrically coupling the at least one first semiconductor element 202 to external, and a second semiconductor element 206. The element 206 spans a spacing 208 between the two inter-connectors 204. The element 206 is operatively affixed to the two interconnectors 204, which may comprise that an electrical coupling is established between the element 206 and one or both of the interconnectors 204.

FIG. 3 is a circuit diagram illustrating an exemplary embodiment 300 of an electronic device within which implementations of semiconductor devices and elements as described herein can be employed. The electronic device 300 can be used, for example, for high voltage applications such as an AC/DC converter, a ballast, e.g., a lamp ballast, etc.

An input stage 302 of the electronic device 300 may comprise a rectifying component and may be configured for receiving an AC of, for example, between 85 volts to 265 volts. An inductor 304, a power transistor 306, a power diode 308, and a capacitor 310 can form a high frequency switching component operable at switching frequencies of, for example, 40 kilohertz to 60 kilohertz, or more. Semiconductor devices 312 and 314 may each comprise a power transistor and power diode combination and may cooperatively operate, in combination with further semiconductor elements such as inductor 316 and capacitor 318, to implement a further rectification component of electronic device 300 configured for a DC output. An input power and/or output power of the electronic device 300 could be, for example, between 18 watts and 200 watts.

Each of semiconductor elements 306, 308, 312, and 314 comprises active semiconductor elements such as power diodes or power transistors. Each of the elements 306, 308, 312, and 314 can be provided included in a semiconductor device. For example, a power package 320 is indicated with a dashed line in FIG. 3 as housing the power transistor 306 and the power diode 308, a power package 322 is indicated as housing the semiconductor device 312, and a power package 324 is indicated as housing the semiconductor device 314.

Each of semiconductor elements 304, 310, 316, and 318 comprises passive semiconductor elements such as inductors and/or capacitors. It is noted that any of the semiconductor devices 320, 322, and 324, for example, may be implementation examples of semiconductor devices as referred to herein; any of the semiconductor elements 304, 310, 316, and 318, for example, may be implementation examples of passive semiconductor elements as referred to herein.

The passive semiconductor elements may be electrically connected to the active semiconductor elements; more specifically, for example, one or both of the inductor 304 and capacitor 310 may be connected to the power package 320, and the inductor 316 and capacitor 318 may be connected according to various configurations to one or both of power packages 322 and 324. Various implementation examples may comprise that one or both of the inductor 304 and capacitor 310 are affixed to contact terminals of power package 320, and the inductor 316 and capacitor 318 are affixed to contact terminals of one or both of power packages 322 and 324. Such affixing may be performed according to any of the method aspects discussed herein. A configuration prior to or resulting from such affixing may represent an implementation example of a configuration of one or more semiconductor devices and/or one or more semiconductor elements as discussed herein.

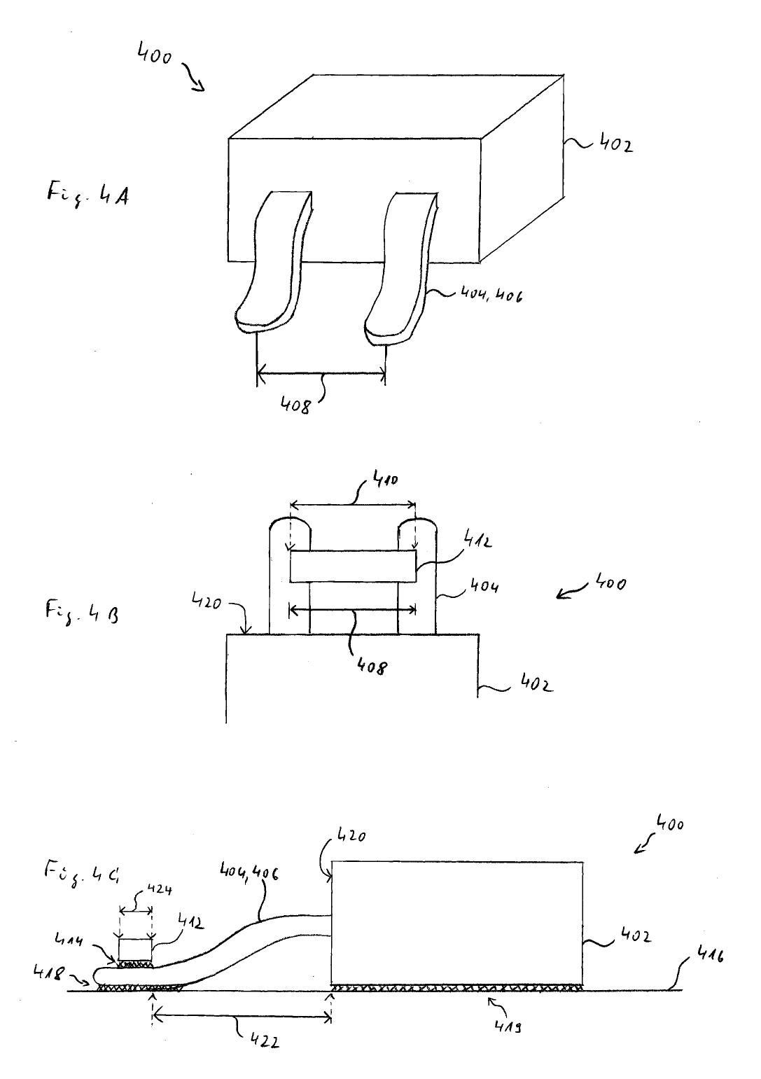

FIGS. 4A to 4C illustrate an embodiment 400 of a semiconductor device in a perspective view (FIG. 4A), a top view (FIG. 4B) and a side view (FIG. 4C). The device 400 may be an implementation example of any of the semiconductor devices 100, 200, 320, 322 and 324 of the previous figures. The device 400 comprises a housing 402 which may integrate one or more active semiconductor elements such as, for example, the power transistor 306, power diode 308, or the semiconductor device 312 or 314 of FIG. 3. The device 400 comprises two interconnectors 404, from which only contact terminals 406 for providing electrical connectivity to external are illustrated. The terminals 406 are implemented as leads 406.

The leads 406 are arranged at a pitch 408 which is the separation thereof measured center-to-center, as indicated in FIGS. 4A and 4B. As further illustrated in FIG. 4B, the pitch 408 of leads 406 is specifically adapted to correspond to a size 410 of a semiconductor element 412 which may implement, for example, a capacitor such as capacitors 310 or 318 of FIG. 3, or an inductor such as inductors 304 or 316 of FIG. 3. The size 410 is illustrated in the example of FIG. 4B as referring to a major dimension of element 412, i.e. its length end-to-end. According to other embodiments, the size of a semiconductor element may refer to any dimension thereof, for example its width or height, and may in general refer to a separation of a pair of contact terminals thereof, wherein the term ‘contact’ may imply electrical, mechanical, and/or thermal contact.

The side view of FIG. 4C illustrates the arrangement of element 412 on leads 404, 406. An affixing of element 412 to leads 406 can be effected, for example, by soldering, which is indicated in FIG. 4C by the presence of a layer 414 of soldering material. Device 400 is shown mounted on a carrier 416 by means of layers 418 and 419 of a mounting material, such as a soldering material or an adhesive material. The processes of affixing element 412 to leads 406 and of mounting device 400 to carrier 416 can be separate processes, or can be one and the same process. For example, the layers 414, 418 can be provided and/or soldered in one step. Additionally or alternatively, a positioning of device 400 onto the carrier 416, and of element 412 onto the leads 406 can be performed in one step.

The semiconductor element 412 is generally arranged in parallel and/or along a surface wall 420 of housing 402 (FIG. 4B), which arrangement may minimize a footprint for the combination of device 400 and element 412. Additionally or alternatively, a commutation loop of an electrical circuit including semiconductor element 412 and a semiconductor element housed within device 400 may be minimized.

The semiconductor element 412 is shown affixed at a separation 422 from housing 402 (FIG. 4C), wherein the separation 422 can measure less than 5 millimeters, or less than 2 millimeters, or less than 1 millimeter, or less than 0.5 millimeters, for example. According to various embodiments, a separation between a semiconductor element, when affixed at contact terminals of a semiconductor device, and a housing of the semiconductor device can be less than a dimension of the semiconductor element, for example less than a length or width thereof. While the element 412 is shown separated from the housing 402 at a comparatively large distance 424 for sake of illustration in FIG. 4C, in other embodiments the semiconductor element 412 would be affixed at a separation of less than a width 424 thereof. In some embodiments a semiconductor element can be affixed at contact terminals of a semiconductor device and in direct mechanical contact with a housing of the semiconductor device.

The leads 406 may be available for providing further contact, despite the semiconductor element 412 being affixed thereto. For example, one or both of leads 406 may establish electrical contact to carrier 416, e.g., via layer 418 and/or to conductor paths printed on carrier 416.

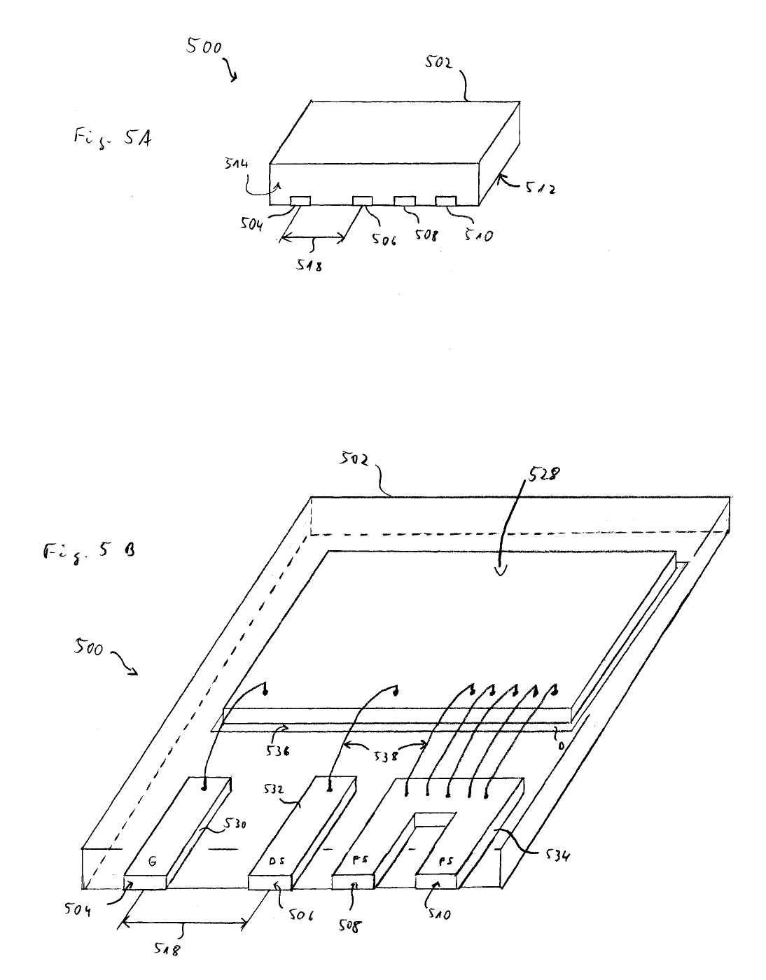

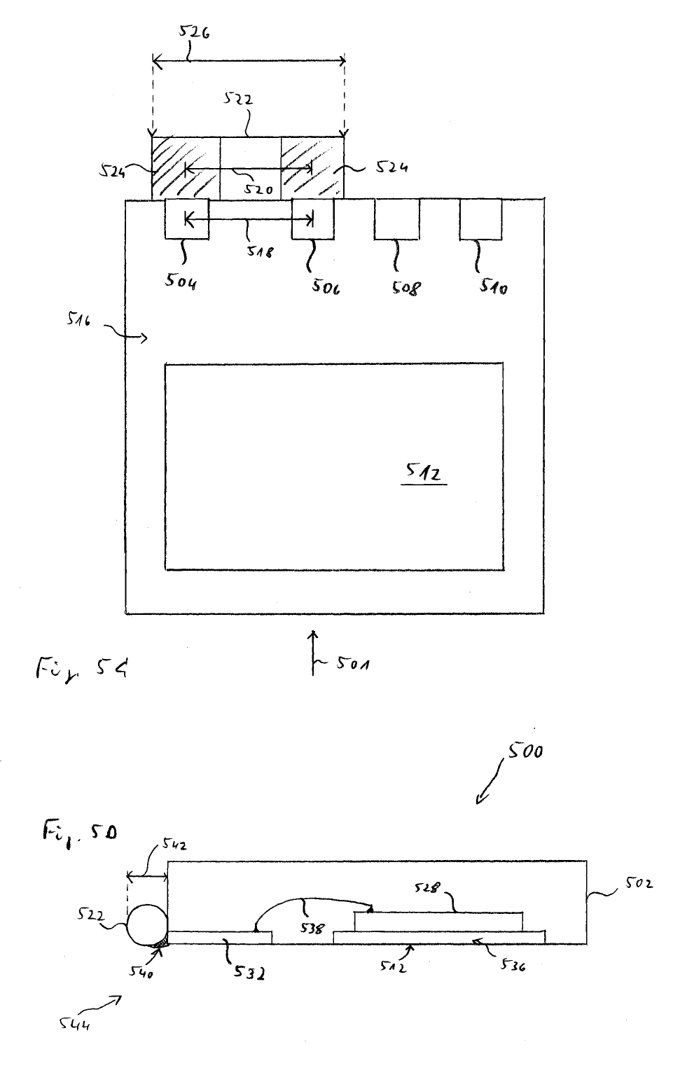

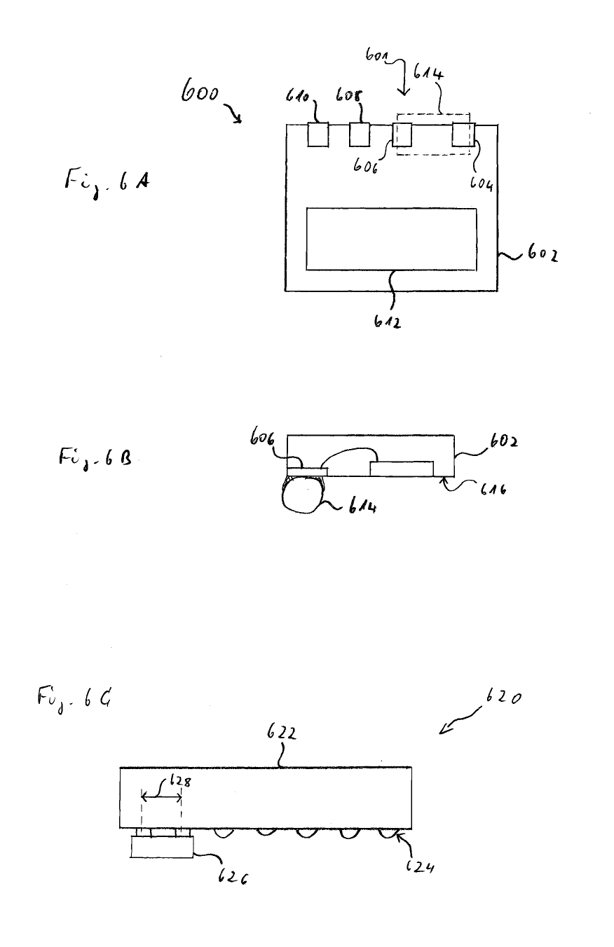

FIGS. 5A to 5D illustrate an embodiment 500 of a semiconductor device in a perspective view (FIG. 5A), a partially transparent view (FIG. 5B), a bottom view (FIG. 5C), and a cross-sectional side view (FIG. 5D) onto a plane as indicated by arrow 501 in FIG. 5C. The device 500 comprises a housing 502 with embedded contact pads 504, 506, 508, 510 on lower portions of front side 514 of housing 502, and contact pad 512 on a bottom surface 516.

As illustrated particularly in FIG. 5B, semiconductor device 500 includes a semi-conductor element 528, which can be an active semiconductor element comprising, for example, a power transistor, a power diode, or a combination of active semiconductor elements. For example, device 500 may implement at least one of the transistor-diode combinations 320, 322 and 324 including active elements 306/308, 312, and 314, respectively, of FIG. 3.

Interconnectors 530, 532, 534 and 536 are provided for electrical coupling of element 528 to external via the respective contact terminals 504 to 512 thereof. Wire-bondings 538 provide for a coupling of element 528 with interconnectors 530 to 536. According to a non-limiting example, element 528 may comprise a power transistor, and contact pad 504 may provide for a gate connectivity, contact pad 506 may provide for a driver source connectivity, contact pads 508 and 510 may provide for a power source connectivity, and contact pad 512 may provide for a drain connectivity.

FIGS. 5C and 5D illustrate the semiconductor device 500 with a semiconductor element 522 affixed to contact pads 504 and 506. The element 522 may comprise a passive semiconductor element; for example, the element 522 may implement one of capacitors 310 and 318, and/or one of inductors 304 and 316 of FIG. 3. In some embodiments, the semiconductor element 522 may comprise one or more active elements such as, for example, one or more diodes. While the element 522 is shown as electrically connecting gate 504 and drain source 506 contact pads of device 500, according to various other embodiments, an element such as element 522 may electrically connect any two (or more) contact terminals of a device or package, and may, for example, provide a drain-source connection, an anode and/or cathode connection for diodes, a source-cathode connection for a transistor-diode combination, etc.

The semiconductor element 522 is arranged in direct contact with the housing 502 of device 500. As illustrated in FIG. 5D, an affixing material 540 may be provided for achieving an affixing by at least one of, for example, soldering and gluing to each of contact pads 504 and 506. Referring exemplarily to soldering, the solder material 540 may be provided for diffusion soldering, reflow soldering, etc. The term ‘direct contact’ may be understood as comprising a touching of housing 502 with a surface of element 522. Direct contact may provide enhanced mechanical stability to the entity comprising device 500 and element 522.

According to one embodiment, mechanical affixing may be achieved, for example, via gluing, while an electrical connection between semiconductor device and a semiconductor element can be achieved additionally or alternatively by wire bonding. Embodiments can be contemplated, according to which a semiconductor device and a semiconductor element are affixed with a small separation; referring for illustrative reasons to the figures, for example, a separation between element 522 and housing 502 of device 500 can be less than a width 542 of semiconductor element 522. For instance, one or both of element 522 and device 500 can be mounted to a common carrier.

An entity 544 including device 500 and element 522 can be manufactured as a movable good or article. The entity 544 may be mounted to a carrier. According to one alternative, device 500 can be mounted to a carrier such as a PCB, an adapter board, etc., prior to affixing element 522 to one or both of device 500 and the carrier.

Referring particularly to FIGS. 5A, 5B and 5C, a pitch 518 between contact pads 504 and 506 of device 500 corresponds to a size 520 of semiconductor element 522; in the specific example described here, the size 520 refers to a separation between contact areas 524 of element 522, see FIG. 5C. The term ‘size of an element’ may refer to a separation of electrical contact terminals such as contact wires, contact pins, etc., of a semiconductor element, as of relevance for an electrical connection with a semiconductor device such as device 500, while geometrical sizes of the semiconductor element may differ from that ‘electrical size’ depending on the arrangement of the contact terminals on the element.

It is noted that in FIG. 5C the size 520 of element 522 is indicated as measuring a center-to-center separation of contact areas 524, while according to other conventions a size may relate, for example, to an end-to-end measurement 526, which would result in a different number value for a contact separation, despite the pitch size 518 of course still corresponding to a spacing of the contact areas 524. Therefore, the aspect of a spacing between two interconnectors corresponding to a size of a semiconductor element should be understood herein as being independent of any particular measurement convention.

The pitch 518 between contact pads 504 and 506 may have been specifically adapted for a set of semiconductor elements comprising element 522, wherein the elements of the set have one and the same size (in the sense as discussed above). Generally, any of the pitches between pairs of contact pads of the device 500 can be specifically selected to correspond to a size of a semiconductor element such as element 522 (or sets of such elements), which does not exclude that one or more of the pitches can be conventionally selected.

In one specific example, conventional pitch sizes may be selected from values of, e.g., 1 millimeter, 2 millimeters, 3 millimeters, etc., while pitch sizes corresponding to sizes of semiconductor elements may be selected from values such as, e.g., 0.1 inches, 0.2 inches, 0.3 inches, etc. Referring to the figures, for example the power package device 500 may have the pitch 518 synchronized to the size 520 of the passive semiconductor element 522, while the pitches of the further contact pads 508 and 510 may be conventionally selected and may therefore not conform to, for example, standard capacitor or inductor sizes.

Even in case a pitch such as pitch 518 of device 500 has been specifically selected for synchronization with semiconductor elements including element 522, the device 500 can still be adapted for different applications. For example, a set of elements of the same size may include elements with different electrical capabilities such as, e.g., resistivity, capacity, and/or inductivity. For any particular application the semiconductor device 500 may therefore be equipped with an appropriate element 522 of the set of semiconductor elements of one and the same size.

Referring exemplarily to the view of FIG. 5C, it is noted that an electric loop including semiconductor element 522, contact pads 504 and 506, interconnectors 530 and 532, wire bonding 538, and semiconductor element 528, may enclose an area smaller than an area enclosed by a loop resulting from providing each of device 500 and element 522 separately on a carrier, or even on separate carriers. Therefore the arrangement shown in FIG. 5C, for example, minimizes a footprint of a circuitry including device 500 and element 522.

For example, a synchronization of active semiconductor devices such as device 500 to passive semiconductor elements such as element 522 in terms of a pitch size (more generally, interconnector spacing) corresponding to an element size, allows increasing an integration level and/or meeting board-space limitations in the area of electronic devices such as power supply apparatuses. Moreover, commutation losses also can be minimized; vice versa, due to minimized parasitic effects regarding, e.g., a parasitic inductivity and/or capacity, an application including device 500 and element 522 may be operated at higher frequencies.

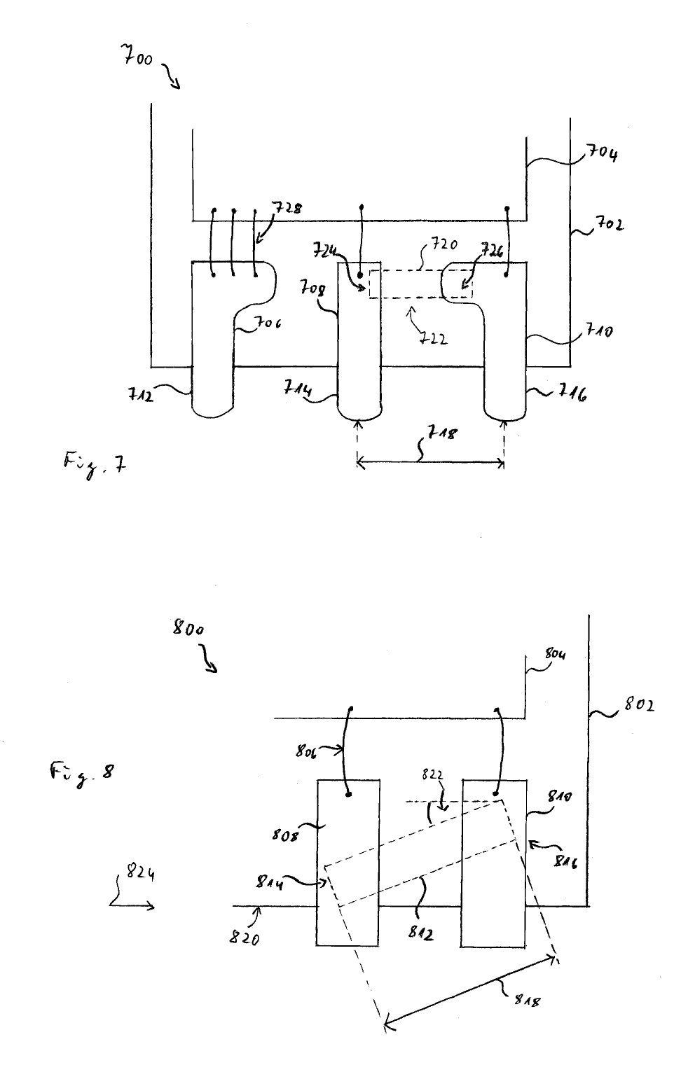

FIGS. 6A and 6B illustrate an embodiment 600 of a semiconductor device in a bottom view (FIG. 6A) and a cross-sectional side view (FIG. 6B) onto a plane as indicated by arrow 601 in FIG. 6A. The device 600 may be a variant of device 500 of FIGS. 5A to 5D. The device 600 comprises a housing 602 with external contact pads 604, 606, 608, 610, and 612, wherein aspects related to the contact pads 604 to 612 may be similar to aspects discussed for the contact pads 504 to 512 of semiconductor device 500 of FIGS. 5A to 5D.

A semiconductor element 614 may have similar properties as has been discussed for element 522 of FIGS. 5C and 5D. According to one embodiment, element 614 is identical to element 522. Element 614 is affixed to contact pads 604 and 606 from below, if referring to surface 616 of device 600 as a bottom surface. FIGS. 6A and 6B therefore illustrate a configuration wherein the device 600 is vertically arranged on top of element 614, i.e. device 600 and element 614 are arranged stack-wise.

FIG. 6C is a schematic side view on an embodiment 620 of a semiconductor device, aspects of which may be similar to what has been discussed above for devices 100, 200, 400, 500 or 600. Device 620 comprises a housing 622 and contact terminals 624 which are implemented as solder balls. A semiconductor element 626 is provided, aspects of which may be similar to what has been discussed above for elements 108, 206, 412, 522 or 614. The element 624 is affixed to the device 620 via at least two of the solder bumps 624. A spacing 628 between a particular pair of solder balls 624 is selected corresponding to a size of element 626, e.g., contact areas thereof. Therefore the configuration of FIG. 6C is another example for a stack-wise arrangement of semiconductor device 620 and semiconductor element 626 affixed to contact terminals 624 thereof.

FIG. 7 is a cross-sectional plan view of an embodiment 700 of a semiconductor device, aspects of which may be similar to what has been discussed above for devices 100, 200, 400, 500, 600, or 620. Device 700, which may implement a power package, comprises a housing 702, a semiconductor element 704, and multiple interconnectors 706, 708, and 710. The element 704 may comprise an active element such as a power transistor, power diode, etc. The interconnectors 706 to 710 provide electrical connectivity to external via contact pins 712, 714 and 716.

The interconnectors 708 and 710 are adapted via their contact pins 714 and 716 to provide a pitch 718 for external electrical connection. Internally, i.e. within the housing 702, the interconnectors 708 and 710 provide areas 724 and 726, respectively, with a spacing 722 thereinbetween. A semiconductor element 720, aspects of which may be similar to what has been discussed above for elements 108, 206, 412, 522, 614, or 626, spans the spacing 722. The element 720 may comprise a passive element, which is operatively affixed to the interconnectors 708, 710, i.e. may provide an electrical connection between areas 724 and 726.

The spacing 722 between the areas 724 and 726 has been selected corresponding to the size of semiconductor element 720. At the same time, the interconnectors 708 and 710 provide a pitch 718 for connectivity to further or other external components, such as conductor paths, boards, other semiconductor devices, etc., wherein the pitch 718 can be different from the spacing 722. As another example, a further semiconductor element with a size corresponding to pitch 718 may be affixed to contact pins 714 and 716 in a way as described for various embodiments herein.

The semiconductor element 720 may be integrated within the housing 702. For example, during a manufacture of semiconductor device 700, the element 720 can be affixed to the areas 724, 726. A subsequent encapsulation process may comprise encapsulation of the active semiconductor element 704, a wire-bonding 728, internal portions of the interconnectors 706 to 710 including the areas 724, 726, and the passive semiconductor element 720.

FIG. 8 is a cross-sectional cut-out top plan view of an embodiment 800 of a semiconductor device, aspects of which may be similar to what has been discussed above for devices 100, 200, 400, 500, 600, 620, or 700. The device 800 comprises housing 802, a first semiconductor element 804, e.g., an active element, wire-bonding 806 and interconnectors 808, 810. A semiconductor element 812, e.g., a passive element, is arranged between electrically conductive areas 814 and 816 of interconnectors 808 and 810, respectively. The element 812 can be operatively affixed to the interconnectors 808, 810 similar to what has been described elsewhere herein.

The element 812 may be integrated within housing 802 in a way similar to what has been described for element 720 in FIG. 7. A spacing 818 between the areas 814, 816 is selected corresponding to a length of the semiconductor element 812. However, in contrast to other embodiments described herein, the element 812 is not arranged in parallel to a surface 820 of housing 802, but at a non-vanishing angle 822. The angle 822 may have any value between 0° and 90° (referring to a full circle of 360°).

Affixing the element 812 at an angle to main dimensions of the device 800 may increase a design flexibility; for example, a layout of the device 800 may be made more compact with reference to a dimension as indicated by arrow 824. According to other embodiments, a semiconductor element may be arranged at a non-vanishing angle also externally of a housing of a semiconductor device.

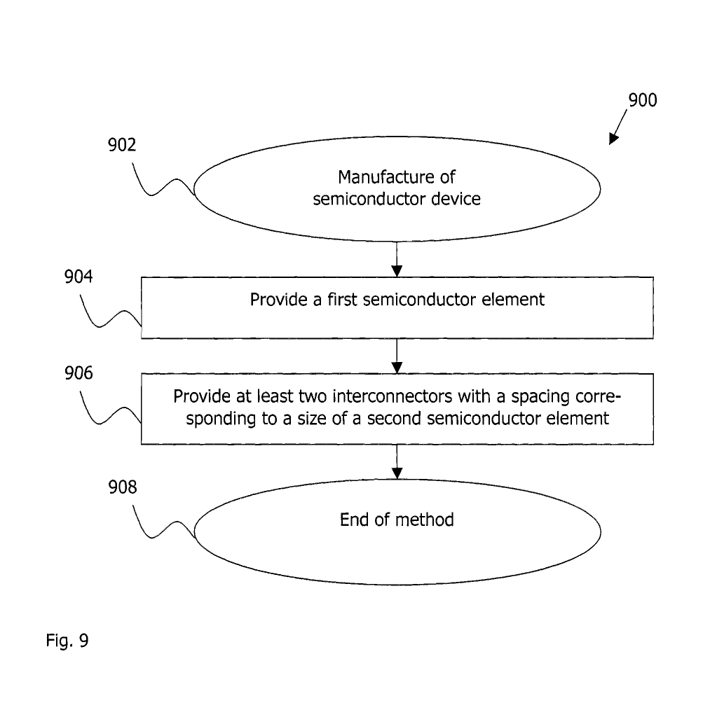

FIG. 9 is a flow diagram illustrating an embodiment 900 of a method of manufacturing a semiconductor device (902). Any of the semiconductor devices discussed herein may be manufactured accordingly. While method 900 is shown as comprising a particular sequence of steps, according to other embodiments the sequence of steps may be changed, and/or any pairs of steps may be performed in parallel to each other.

In step 904, at least one first semiconductor element is provided, for example an active semiconductor element and/or a power semiconductor element, such as a power transistor or power diode, may be provided. In step 906, at least two interconnectors are provided for electrically coupling the at least one first semiconductor element to external. A spacing between the two interconnectors, for example a pitch, is selected corresponding to a size of a second semiconductor element to thereby achieve a synchronization of interconnector spacing and element size. The method 900 ends in step 908. The second semiconductor element may or may not be subjected to the method 900.

According to various embodiments, a pitch of the two interconnectors is selected for synchronization purposes corresponding to a maximum dimension, e.g., a length, of the second semiconductor element. For example, the second semiconductor element may be a passive element and may conform to a coding of sizes of passive semiconductor elements, e.g., an internationally agreed coding for resistors, capacitors, and/or inductors, etc. The interconnector pitch may be selected in conformance to the coding, e.g., may be selected corresponding to one of the sizes prescribed by the coding.

Providing the interconnectors may comprise, in a pinning subprocess, providing contact pins (or other contact terminals such as pads, leads, etc.), which are required in order for affixing the desired second semiconductor element thereto. For example, in case the second semiconductor element is to be affixed outside of a housing of the semiconductor device, the required contact pins have to be provided to external, wherein the contact pins may be provided such that they are available for further contacting besides establishing contact with the second semiconductor element.

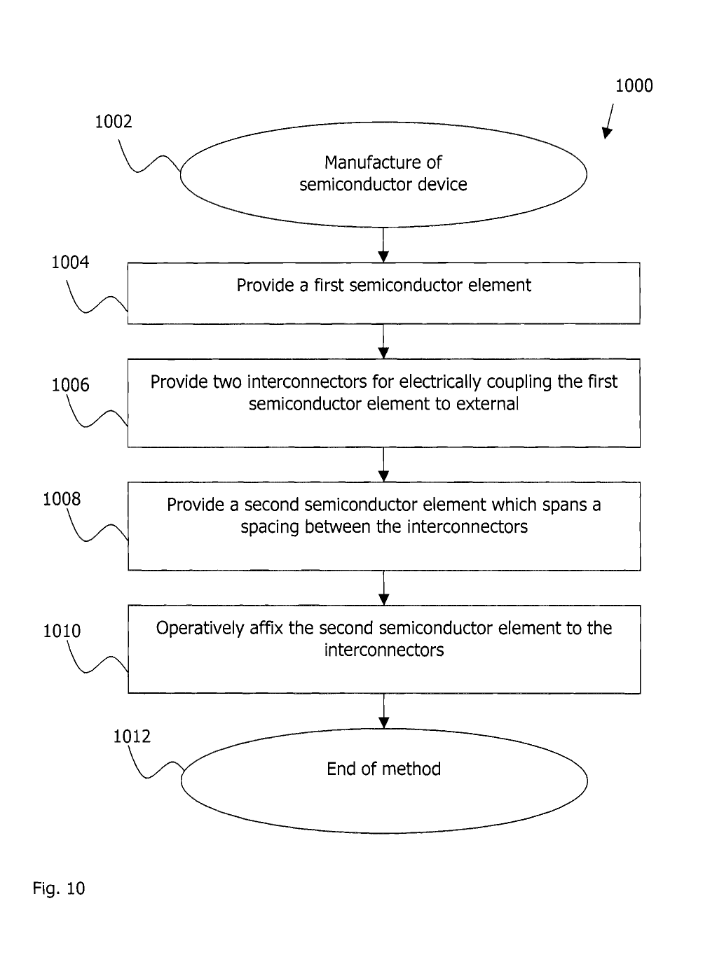

FIG. 10 is a flow diagram illustrating an embodiment 1000 of a method of manufacturing a semiconductor device (1002). The method 1000 may be a variant of method 900 of FIG. 9. In step 1004, at least one first semiconductor element is provided. In step 1006, at least two interconnectors are provided for electrically coupling the at least one first semi-conductor element to external. In step 1008, a second semiconductor element is provided which spans a spacing between the two interconnectors. In step 1010, the second semiconductor element is operatively affixed to the two interconnectors. The method ends in step 1012.

According to one example, the process 1000 may result in an entity comprising a power package as an implementation of the semiconductor device, wherein a passive semiconductor element such as a capacitor has been mounted, e.g., via soldering, to contact terminals of the package, wherein a pitch of the contact terminals conforms to a size of the passive element in terms of electrical contact areas or points thereof. The resulting entity may further be processed by a mounting thereof onto a carrier, etc.

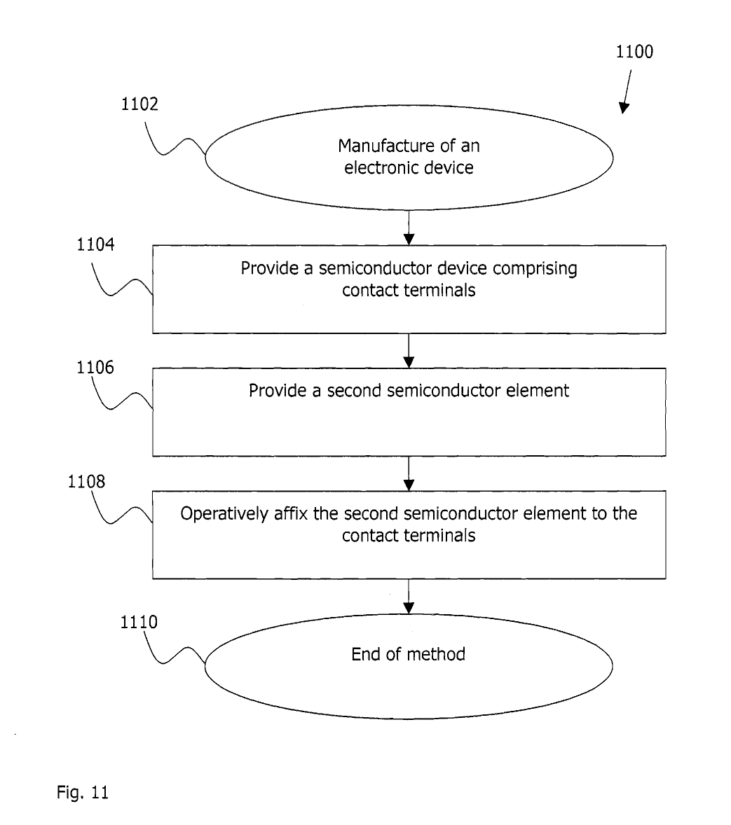

FIG. 11 is a flow diagram illustrating an embodiment 1100 of a method of manufacturing an electronic device (1102). According to one example, the electronic device may relate to a power supply such as the switched mode power supply 300 illustrated in FIG. 3. In step 1104, a semiconductor device is provided which comprises a first semiconductor element, a housing, and two contact terminals accessible from outside the housing. A pitch of the two contact terminals may correspond to a size of a second semiconductor element, which may or may not be present. The semiconductor device may for example comprise a power package housing a power transistor, power diode, power chip, etc.

In step 1106, a second semiconductor element is provided, for example, a passive element such as a capacitor or inductor. In step 1108, the second semiconductor element is operatively affixed to the two contact terminals, which includes that an electrical connectivity between the semiconductor device and the second semiconductor element is established which enables performing an electronic functionality during an operation of the electronic device. The affixing of the second semiconductor element to the contact terminals of the semiconductor device may comprise establishing a direct mechanical contact, which is to be understood as including the presence of one or more mediating layers of affixing material, for example of one or more soldering layers, adhesive layers, etc. The method 1100 ends with step 1110.

In a process of manufacturing a semiconductor device and/or an electronic device, a reflow soldering technique may be used for affixing the second semiconductor element to the desired interconnectors, e.g., contact terminals thereof. In a preparatory step, a soldering material may be provided to the interconnectors, the second semiconductor element, or both. The preparatory step can be performed during a manufacture of the semiconductor device, e.g., prior to a process of affixing the second semiconductor element, and/or during the affixing process.

In a main process step, which may or may not be performed in the same process as the preparatory step, the soldering material may be molten, for example, in a reflow oven, and as a result the second semiconductor element is soldered to the interconnectors, e.g., the contact terminals thereof. The main step may include a soldering of the semiconductor device to a carrier such as a PCB, an auxiliary card, etc. In some embodiments, a soldering of the semiconductor device to the carrier, a soldering of the second semiconductor element to the semiconductor device, and/or a soldering of the second semiconductor element to the carrier is performed in parallel, for example in a reflow oven.

The process 1100 may be performed immediately subsequently to a manufacturing of the semiconductor device integrated into the electronic device in step 1104. In an alternative embodiment, the manufacturing of the semiconductor device and the manufacturing of the electronic device are separate processes. For example, the semiconductor device may be stored, shipped, and/or may be subjected to other processing after its manufacture and before being used in step 1104 of process 1100.

The process 1100 differs from processes according to which, for example, each of a power package and a passive component is separately mounted on a carrier, or on two carriers, such as PCBs, and where the package and the component are interconnected by conductor paths or similar means traversing the one or more carriers, resulting in a comparatively large footprint and/or commutation loop.

The process 1100 also differs from a process wherein a passive component is integrated into an integrated circuit or chip within a package. While such process may provide for a small footprint and/or commutation loop, one specific package for each application has to be provided, different applications generally require application-specific adaptations of the passive component, and therefore a corresponding number of specifically adapted packages has to be provided, resulting amongst others in smaller lot sizes and a loss of flexibility and/or higher complexity of subsequent processes related to electronic device manufacture.

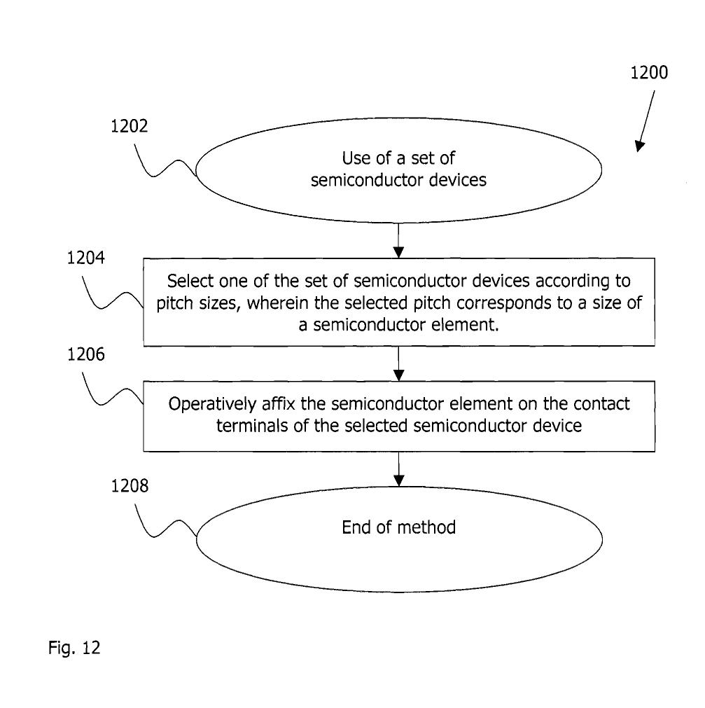

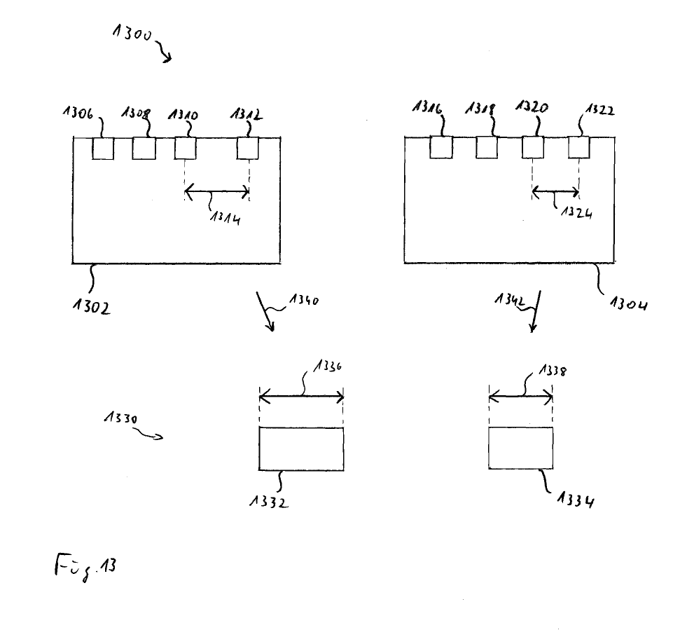

FIG. 12 is a flow diagram illustrating an embodiment 1200 of a method of using a set of semiconductor devices (1202). The method 1200 is described with reference to an exemplary set 1300 of devices illustrated in FIG. 13. The set 1300 comprises at least two semiconductor devices 1302 and 1304. The device 1302 comprises contact pads 1306, 1308, 1310 and 1312. The semiconductor device 1304 comprises four contact pads 1316, 1318, 1320 and 1322. The device 1302 has a pitch 1314 between pads 1310 and 1312, and the device 1304 has a pitch 1324 between pads 1320 and 1322, wherein the pitch 1314 differs from the pitch 1324. As an example, the pitch 1314 may be 2/10 inch, while the pitch 1324 may 1/10 inch.

The devices 1302 and 1304 may or may not encase a similar active semiconductor element. Purely for reasons of illustration, one or both of the semiconductor devices 1302 and 1304 may, for example, be realizations of one or more of packages 320, 322, and/or 324 illustrated in FIG. 3. According to one example, device 1302 implements package 320, while device 1304 implements packages 322/324 (packages 322 and 324 may be identical in the configuration of FIG. 3). According to another example, each of devices 1302 and 1304 implements package 320, or package 322/324, albeit with different pitches.

One or both of pitch sizes 1314 and 1324 may be selected for purposes of synchronization of the device 1302 and/or 1304 to a size of a passive semiconductor element or to sizes of multiple passive semiconductor elements. According to various embodiments, pitch sizes 1314 and 1324 are selected corresponding to passive semiconductor element sizes as prescribed according to a respective international coding. As a result, pitch 1314 may be adapted to a set of semiconductor elements of one and the same first size and differing electrical properties such as resistance, capacitance, and/or inductance, while pitch 1324 may be adapted to a different set of semiconductor elements of one and the same second size and differing electrical properties.

For example, a series 1330 comprising at least semiconductor elements 1332 and 1334 is illustrated in FIG. 13. Element 1332 may represent a set of passive semiconductor elements of fixed size 1336 and varying electrical properties, and element 1334 may represent a set of passive semiconductor elements of fixed size 1338 and varying electrical properties. As indicated by arrows 1340, 1342, pitch size 1314 has been selected corresponding to size 1336, while pitch size 1324 has been selected corresponding to size 1338.

Referring to process 1200 in FIG. 12, in step 1204, one of the set 1300 of semiconductor devices 1302, 1304 is selected according to a pitch 1314 or 1324 between two contact terminals 1310/1312 or 1320/1322 accessible from outside a housing of each of the semiconductor devices 1302, 1304. The selected pitch from the set of pitches 1314, 1324 may correspond to one of the sizes 1336, 1338 of semiconductor elements 1332, 1334. For example, for a manufacture of a particular electronic device, a combination of device 1302 and one of the set of elements represented by element 1332 with size 1336 may be selected. The combination may be selected based primarily on either one of the electrical or electronic properties of device 1302 or element 1332.

In step 1206, the semiconductor element 1332 fitting to pitch size 1314 is operatively affixed to the contact pads 1310, 1312 of the selected semiconductor device 1302. In step 1208, the process 1200 ends.

As used herein, to the extent that terms such as “include,” “have,” “with,” or variants thereof are used in either the detailed description or the claims, it is to be understood that such terms are intended to be inclusive in a manner similar to the term “comprise.” The term “exemplary” is meant to merely denote one or an example, rather than the best or optimum example according to any given criterion.

While a particular feature or aspect of an embodiment of the invention may have been disclosed with respect to only one of several implementations, such feature or aspect may be combined with one or more other features or aspects of the other implementations as may be desired and advantageous for any given or particular application.

While specific embodiments have been illustrated and described herein, it will be appreciated by those of normal skill in the art that many modifications may be made, adaptations be performed and variants be implemented in view of the specific embodiments shown and described without departing from the scope of the present invention. Accordingly, it is intended that any such modifications, adaptations and variations of the specific embodiments discussed herein are covered and the invention be limited only by the scope of the claims.

What is claimed is:

1. A semiconductor device, comprising:
a first semiconductor element;
two interconnectors for electrically coupling the first semiconductor element externally; and
a second semiconductor element spanning a spacing between the two interconnectors and operatively affixed to the two interconnectors.

2. The semiconductor device of claim 1, wherein:
the first semiconductor element comprises an active semiconductor element; and
the second semiconductor element comprises a passive semiconductor element.

3. The semiconductor device of claim 1, further comprising:
a housing encapsulating the first semiconductor element;
wherein the two interconnectors each comprise a contact terminal accessible from outside the housing, and
wherein a pitch between the contact terminals corresponds to a size of the second semiconductor element.

4. The semiconductor device of claim 1, further comprising a housing encapsulating the first semiconductor element, wherein the second semiconductor element is integrated within the housing.

5. The semiconductor device of claim 3, wherein the second semiconductor element is affixed at a separation from the housing of less than 2 millimeters, or less than a width of the second semiconductor element, or is affixed in direct contact with the housing.

6. The semiconductor device of claim 3, wherein:
the contact terminals comprise contact pads, contact pins, and/or leads; and
the second semiconductor element is affixed to a pair of the contact pads, the contact pins, and/or the leads.

7. The semiconductor device of claim 1, wherein the first and the second semiconductor elements are affixed stackwise to each other.

8. The semiconductor device of claim 1, wherein the first and/or the second semiconductor element comprises a power semiconductor element.

9. The semiconductor device of claim 8, wherein:
the first semiconductor element comprises a power transistor or a power diode; and
the second semiconductor element comprises a capacitor or an inductor.

10. The semiconductor device of claim 3, wherein the first semiconductor element is within a package adapted for surface mounting and wherein the second semiconductor element is affixed externally to the package.

11. A semiconductor device, comprising:
an active semiconductor component including two interconnectors for electrically coupling the active semiconductor component to externally, the two interconnectors spaced by a first dimension; and
a passive semiconductor element having a length corresponding to the first dimension and being affixed to the two interconnectors.

12. The semiconductor device of claim 11, wherein the active semiconductor component further comprises a housing, wherein the two interconnectors each comprise a contact terminal accessible from outside the housing, and wherein a pitch between the contact terminals corresponds to the length of the passive semiconductor element.

13. The semiconductor device of claim 11, wherein the active semiconductor component further comprises a housing, wherein the passive semiconductor element is integrated within the housing.

14. The semiconductor device of claim 11, wherein the active semiconductor component further comprises a housing, wherein the two interconnectors are configured for the passive semiconductor element to be arranged along a wall of the housing.

15. The semiconductor device of claim 11, wherein the active semiconductor element comprises a power semiconductor element.

16. The semiconductor device of claim 11, wherein the active semiconductor element is configured for a high voltage application.

17. The semiconductor device of claim 11, wherein the active semiconductor device and the passive semiconductor device are integrated in a power package adapted for surface mounting.

18. A method of manufacturing a semiconductor device, the method comprising:
providing an active semiconductor component that includes two interconnectors for electrically coupling the active component externally, the two interconnectors spaced by a first dimension;
providing a passive semiconductor element having a length corresponding to the first dimension so that the passive semiconductor element can be affixed to the two interconnectors; and
affixing the passive semiconductor element to the two interconnectors.

19. A method of manufacturing a semiconductor device, the method comprising:
providing a first semiconductor element; and
providing two interconnectors for electrically coupling the first semiconductor element externally, wherein a spacing between the two interconnectors is selected which corresponds to a size of a second semiconductor element.

20. The method of claim 19, further comprising selecting a pitch of the two interconnectors according to a length of the second semiconductor element.

21. A method of manufacturing an electronic device, the method comprising:
providing a semiconductor device comprising a first semiconductor element, a housing, and two contact terminals accessible from outside the housing, wherein a pitch between the two contact terminals corresponds to a size of a second semiconductor element;
providing the second semiconductor element; and
operatively affixing the second semiconductor element to the two contact terminals.

22. The method of claim 21, further comprising:
providing a carrier; and
reflow soldering the semiconductor device or the second semiconductor element to the carrier.

23. A method of using a set of semiconductor devices, the method comprising:
selecting one of a set of semiconductor devices according to a pitch between two contact terminals accessible from outside a housing of each of the semiconductor devices, wherein a selected pitch from a set of pitches of the set of semiconductor devices corresponds to a size of a semiconductor element.

24. The method of claim 23, further comprising affixing the semiconductor element on the contact terminals of the selected semiconductor device.
